(19) United States
(12) Patent Application Publication
(10) Pub. No.: US 2023/0360963 A1
(43) Pub. Date: Nov. 9, 2023

(54) METHOD OF MANUFACTURING SEMICONDUCTOR STRUCTURE AND SEMICONDUCTOR STRUCTURE

(71) Applicant: CHANGXIN MEMORY TECHNOLOGIES, INC., Heifei City (CN)

(72) Inventor: Junsheng ZANG, Hefei City (CN)

(21) Appl. No.: 17/810,034

(22) Filed: Jun. 30, 2022

Related U.S. Application Data
(63) Continuation of application No. PCT/CN2022/094659, filed on May 24, 2022.

(30) Foreign Application Priority Data
May 5, 2022 (CN) 202210477973.9

(51) Int. Cl. H01L 21/768; H01L 21/02; H01L 23/528; H01L 23/535

(52) U.S. Cl. CPC H01L 21/76805; H01L 21/02063; H01L 21/76814; H01L 21/76816; H01L 23/5283; H01L 23/535

(57) ABSTRACT

The present disclosure provides a method of manufacturing a semiconductor structure and a semiconductor structure, and relates to the technical field of semiconductors. The method of manufacturing the semiconductor structure includes: providing a semiconductor base plate with a first contact hole whose pattern on a preset section includes a long sidewall and a short sidewall; forming a sacrificial layer on the long sidewall; and processing the first contact hole to form a second contact hole below the first contact hole, wherein the second contact hole is connected to the first contact hole, a plane parallel to a top surface of the semiconductor base plate is taken as a cross section, and cross-sectional area of the second contact hole is less than cross-sectional area of a partial region of the first contact hole.

### CROSS-REFERENCE TO RELATED APPLICATIONS

This is a continuation of International Application No. PCT/CN2022/094659, filed on May 24, 2022, which claims the priority to Chinese Patent Application No. 202210477973.9, titled “METHOD OF MANUFACTURING SEMICONDUCTOR STRUCTURE AND SEMICONDUCTOR STRUCTURE” and filed on May 5, 2022. The entire contents of International Application No. PCT/CN2022/094659 and Chinese Patent Application No. 202210477973.9 are incorporated herein by reference.

### TECHNICAL FIELD

The present disclosure relates to a method of manufacturing a semiconductor structure and a semiconductor structure.

### BACKGROUND

With the development of an advanced manufacturing process of a semiconductor structure, a height of a device (such as a capacitor structure) in the semiconductor structure is increasing, making a contact structure longer. Before the contact structure is formed, a contact hole needs to be formed in the semiconductor structure. However, when the contact hole is etched, if etching rates of a long sidewall and a short sidewall of the contact hole are different, a bridging defect is caused subsequently, which reduces performance and a yield of the semiconductor structure.

### Summary

An overview of the subject matter detailed in the present disclosure is provided below, which is not intended to limit the protection scope of the claims.

The present disclosure provides a method of manufacturing a semiconductor structure and a semiconductor structure.

A first aspect of the present disclosure provides a method of manufacturing a semiconductor structure, including:
providing a semiconductor base plate with a first contact hole whose pattern on a preset section includes a long sidewall and a short sidewall;
forming a sacrificial layer on the long sidewall; and
processing the first contact hole to form a second contact hole below the first contact hole, wherein the second contact hole is connected to the first contact hole, a plane parallel to a top surface of the semiconductor base plate is taken as a cross section, cross-sectional area of the second contact hole is less than cross-sectional area of a partial region of the first contact hole, and the partial region is a region above a position at which the first contact hole is connected to the second contact hole.

A second aspect of the present disclosure provides a semiconductor structure, including:
a semiconductor base plate, wherein the semiconductor base plate includes a base plate body and a support layer disposed on the base plate body, the support layer is provided with a first contact hole, and a pattern of the first contact hole on a preset section includes a long sidewall and a short sidewall; and
a second contact hole located below the first contact hole, wherein one end of the second contact hole is connected to the first contact hole and the other end of the second contact hole exposes a top surface of the base plate body, a plane parallel to the top surface of the base plate body is taken as a cross section, cross-sectional area of the second contact hole is less than cross-sectional area of a partial region of the first contact hole, and the partial region is a region above a position at which the first contact hole is connected to the second contact hole.

Other aspects of the present disclosure are understandable upon reading and understanding of the accompanying drawings and detailed description.

### BRIEF DESCRIPTION OF THE DRAWINGS

The accompanying drawings incorporated into the specification and constituting part of the specification illustrate the embodiments of the present disclosure, and are used together with the description to explain the principles of the embodiments of the present disclosure. In these accompanying drawings, similar reference numerals are used to represent similar elements. The accompanying drawings in the following description are some rather than all of the embodiments of the present disclosure. Those skilled in the art may derive other accompanying drawings based on these accompanying drawings without creative efforts.

FIG. 1 is a flowchart of a method of manufacturing a semiconductor structure according to an exemplary embodiment;

FIG. 2 is a schematic diagram of forming a support structure layer in a method of manufacturing a semiconductor structure according to an exemplary embodiment;

FIG. 3 is a schematic diagram of a residual particulate impurity in a method of manufacturing a semiconductor structure according to an exemplary embodiment;

FIG. 4 is a schematic diagram of forming a first contact hole in a method of manufacturing a semiconductor structure according to an exemplary embodiment;

FIG. 5 is a schematic diagram of forming an initial sacrificial layer in a method of manufacturing a semiconductor structure according to an exemplary embodiment;

FIG. 6 is a schematic diagram of forming a sacrificial layer on a long sidewall in a method of manufacturing a semiconductor structure according to an exemplary embodiment;

FIG. 7 is a schematic diagram of forming a second contact hole in a method of manufacturing a semiconductor structure according to an exemplary embodiment; and

FIG. 8 is a schematic diagram of forming a contact through hole and a support layer in a method of manufacturing a semiconductor structure according to an exemplary embodiment.

### DETAILED DESCRIPTION

To make the objectives, technical solutions, and advantages of the embodiments of the present disclosure clearer, the following clearly and completely describes the technical solutions in the embodiments of the present disclosure with reference to the accompanying drawings in the embodiments of the present disclosure. Apparently, the described embodiments are some but not all of the embodiments of the present disclosure. All other embodiments obtained by those skilled in the art based on the embodiments of the present disclosure without creative efforts should fall within the protection scope of the present disclosure. It should be noted that the embodiments in the present disclosure and features in the embodiments may be combined with each other in a non-conflicting manner.

With the development of an advanced manufacturing process of a semiconductor structure, a height of a device (such as a capacitor structure) in the semiconductor structure is increasing, making a contact structure longer. Before the contact structure is formed, a contact hole needs to be formed in the semiconductor structure. However, when the contact hole is etched, an impurity generated is easily piled up on a short sidewall of the contact hole. As a result, an etching rate of the short sidewall of the contact hole is less than that of a long sidewall of the contact hole, making a shape of a cross section of the formed contact hole close to an ellipse. Then, in a process of forming the contact structure in the contact hole, a same contact structure may overlap adjacent metal layers or active regions. Because the contact structure is made of a metal conductive material, a bridging defect occurs between the adjacent metal layers or active regions, which reduces performance and a yield of the semiconductor structure.

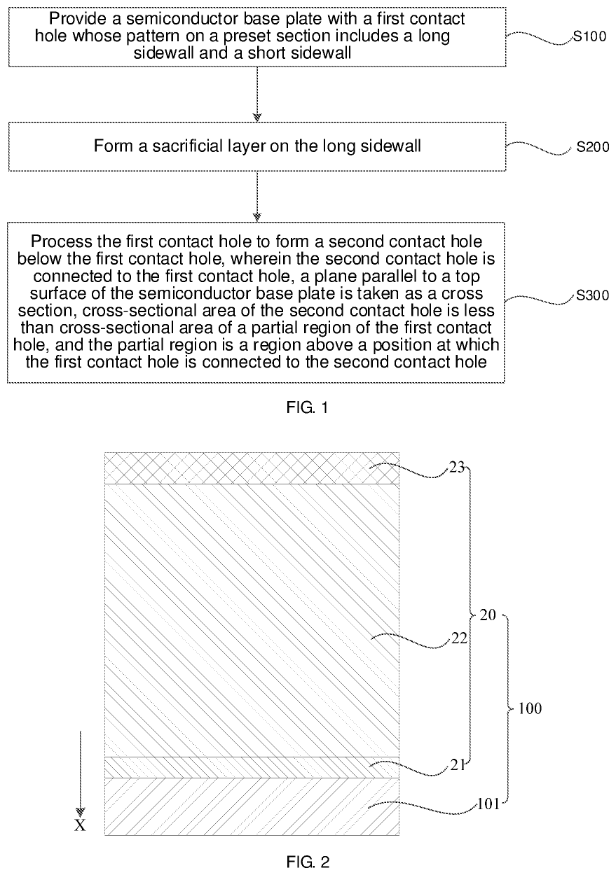

In order to resolve one of the foregoing technical problems, an exemplary embodiment of the present disclosure provides a method of manufacturing a semiconductor structure. The method of manufacturing a semiconductor structure is described below with reference to FIG. 1 to FIG. 8.

A semiconductor structure is not limited in this embodiment. The semiconductor structure is described below by taking a dynamic random access memory (DRAM) as an example, but this embodiment is not limited thereto, and the semiconductor structure in this embodiment may also be another structure.

As shown in FIG. 1, an exemplary embodiment of the present disclosure provides a method of manufacturing a semiconductor structure, including the following steps:

Step S100: Provide a semiconductor base plate with a first contact hole whose pattern on a preset section includes a long sidewall and a short sidewall.

Step S200: Form a sacrificial layer on the long sidewall.

Step S300: Process the first contact hole to form a second contact hole below the first contact hole, wherein the second contact hole is connected to the first contact hole, a plane parallel to a top surface of the semiconductor base plate is taken as a cross section, cross-sectional area of the second contact hole is less than cross-sectional area of a partial region of the first contact hole, and the partial region is a region above a position at which the first contact hole is connected to the second contact hole.

As shown in FIG. 4 and FIG. 8, the plane parallel to the top surface of the semiconductor base plate 100 is taken as the cross section. Any cross section of the first contact hole 11 in a depth direction of the first contact hole 11 can be understood as the preset section, in other words, the preset section may be any cross section that is of the first contact hole 11 along a direction opposite to a first direction X and is in a predetermined height range of the semiconductor base plate 100. The description in this embodiment takes an orientation shown in the figure as an example, and the first direction X is an extension direction from the top surface of the semiconductor base plate 100 to a bottom surface of the semiconductor base plate 100.

Referring to FIG. 6 and FIG. 4, a shape of the cross section of the first contact hole 11 formed by using an etching process includes an ellipse, a sidewall on each side of a long axis of the ellipse is defined as the long sidewall 111, and a sidewall on each side of a short axis of the ellipse is defined as the short sidewall 112.

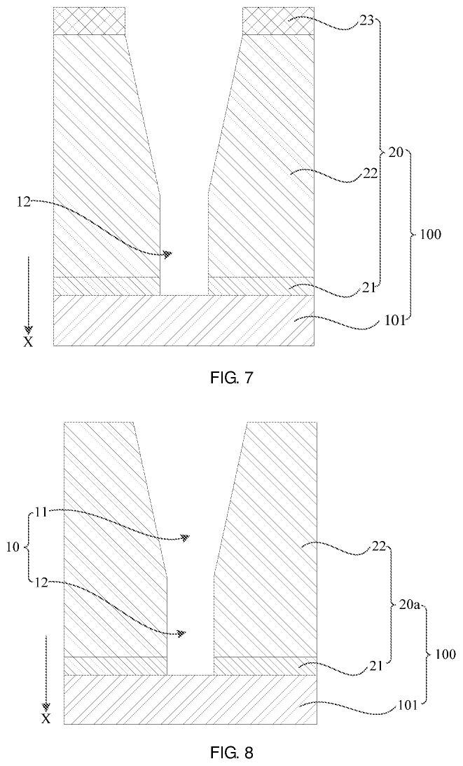

When there is no sacrificial layer 30 on the long sidewall 111 of the first contact hole 11, in a process of etching the second contact hole 12 subsequently (referring to FIG. 7), an etching rate of the long sidewall 111 is less than that of the short sidewall 112, which increases ovality of the shape of the cross section of the first contact hole 11, resulting in a bridging defect subsequently. Therefore, in order to ensure a same etching rate for each sidewall of the second contact hole 12, the sacrificial layer 30 is formed on the long sidewall 111.

After the second contact hole 12 is formed, the sacrificial layer 30 on the long sidewall 111 is removed.

In this embodiment, a contact through hole (including the first contact hole and the second contact hole) is formed by using a two-step etching process. After the first contact hole is formed, the sacrificial layer is deposited on the long sidewall to adjust an etching window. An etch selectivity is controlled to reduce the etching rate of the short sidewall of the first contact hole in a process of forming the second contact hole subsequently, so as to ensure the same etching rate for any sidewall of the second contact hole to effectively avoid inconsistent etching lengths of a long sidewall and a short sidewall of the second contact hole, which can guarantee quality of the formed second contact hole, prevent the bridging defect, and improve performance and a yield of a semiconductor structure.

According to an exemplary embodiment, this embodiment is a further description of step S100 described above.

As shown in FIG. 2, in step S100, the semiconductor base plate 100 with the first contact hole 11 may be provided by using the following method:
providing the semiconductor base plate 100 including a base plate body 101 and a support structure layer 20 disposed on the base plate body 101.

The base plate body 101 is configured to support other components disposed on it. The base plate body 101 may be conductive, for example, may be a base of the semiconductor structure or any metal layer in the semiconductor structure. When the base plate body 101 is the base, the base may be made of a semiconductor material. The semiconductor material may be one or more of silicon, germanium, a silicon-germanium compound, and a silicon-carbon compound. In some embodiments, the base may be made of silicon. The use of silicon as the base is to facilitate understanding of a subsequent forming method by those skilled in the art, rather than to constitute a limitation. In an actual application process, an appropriate material of the base may be selected as required.

When the base plate body 101 is the metal layer, the base plate body 101 is made of at least one of tungsten, copper, aluminum, and polycrystalline silicon, and there may be one metal layer or a plurality of stacked metal layers.

It should be noted that a material of the base plate body provided in the present disclosure may include but is not limited to the above materials. Materials available for the semiconductor base plate are not listed herein, and those skilled in the art can select them based on an actual situation.

The support structure layer 20 disposed on the base plate body 101 can be configured to form a contact hole in a subsequent manufacturing process (in this embodiment, the contact hole includes the first contact hole and the second contact hole). After the contact hole is formed, the support structure layer 20 surrounding the contact hole can be configured to subsequently form another semiconductor structure between adjacent contact holes. When the base plate body 101 is the base, a bit line structure and other semiconductor structures may be formed in the support structure layer 20. When the base plate body 101 is the metal layer, a metal wire layer and the like may be formed in the support structure layer 20.

As shown in FIG. 2, in a process of forming the support structure layer 20, a dielectric layer 21, an isolation layer 22, and a hard mask layer 23 that are stacked can be formed on the base plate body 101 by using an atomic layer deposition process, a chemical vapor deposition process, or a physical vapor deposition process. The dielectric layer 21 is in contact with the base plate body 101, and the isolation layer 22 and the hard mask layer 23 are successively disposed on the dielectric layer 21.

A thickness of the isolation layer 22 may be the same as or different from a thickness of the dielectric layer 21. In an example, the thickness of the isolation layer 22 is greater than the thickness of the dielectric layer 21. A material of the dielectric layer 21 may include, but is not limited to, silicon nitride, silicon oxynitride, and the like. A material of the isolation layer 22 may include, but is not limited to, an oxide or a nitride, such as silicon dioxide, to ensure that the support structure layer 20 has an optimal isolation function. A material of the hard mask layer 23 may include, but is not limited to, carbon, silicon oxide, titanium nitride, or silicon nitride to improve quality of the subsequently formed first contact hole 11 and second contact hole 12. The dielectric layer 21 and the isolation layer 22 can support the subsequently formed contact hole to facilitate formation of another semiconductor structure, while the hard mask layer 23 may be removed in the subsequent manufacturing process of the semiconductor structure.

Finally, the first contact hole 11 is formed in the support structure layer 20, and there is a preset height between the bottom of the first contact hole 11 and the base plate body 101. The preset height is used to form the second contact hole 12 subsequently, and may be flexibly selected based on a thickness of a contact structure to be subsequently formed. A preset height of the second contact hole 12 is the same as or different from a height of the first contact hole 11. For example, the preset height of the second contact hole 12 is greater than the height of the first contact hole 11, or the preset height of the second contact hole 12 is less than or equal to the height of the first contact hole 11.

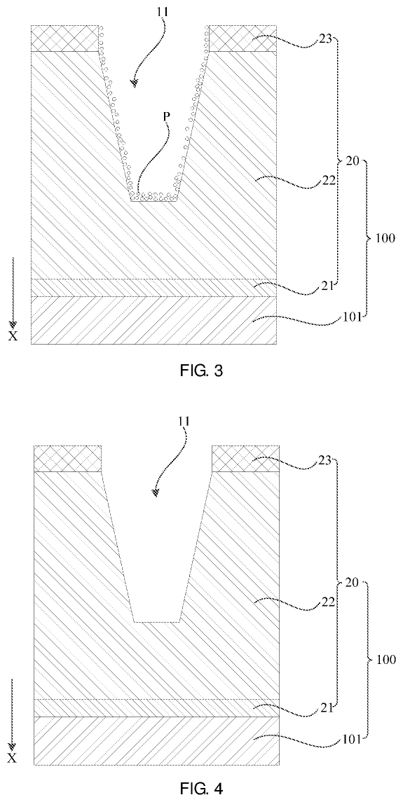

Referring to FIG. 3 and FIG. 4, in some embodiments, the first contact hole 11 may be formed in the support structure layer 20 by using the etching process, and an etching endpoint of the first contact hole 11 may be located in the isolation layer 22. It should be noted that along the first direction X, a depth of the first contact hole 11 is between one-third and two-thirds of the thickness of the isolation layer 22. This reduces difficulty of forming the contact through hole 10 while ensuring conductivity of the subsequently formed contact structure.

In this embodiment, the support structure layer can support the formation of the first contact hole and the second contact hole to ensure sizes of the first contact hole and the second contact hole and improve quality of the subsequently formed contact structure.

As shown in FIG. 6, the pattern, of the first contact hole 11 formed on the support structure layer 20, on the preset section includes the long sidewall 111 and the short sidewall 112. In this embodiment, the plane parallel to the top surface of the semiconductor base plate 100 is taken as the cross section. Any cross section of the first contact hole 11 in the depth direction of the first contact hole 11 can be understood as the preset section, in other words, the preset section may be any cross section that is of the first contact hole 11 along the direction opposite to the first direction X and is in a predetermined height range of the isolation layer 22.

The shape of the cross section of the first contact hole 11 formed by using the etching process includes the ellipse, the sidewall on each side of the long axis of the ellipse is defined as the long sidewall 111, and the sidewall on each side of the short axis of the ellipse is defined as the short sidewall 112.

As shown in FIG. 3 and FIG. 6, the first contact hole 11 is formed by using the etching process. In the etching process, a particulate impurity P such as an oxide is left on a bottom surface and the sidewall of the first contact hole 11. The particulate impurity P reduces purity of the subsequently formed sacrificial layer 30, thereby reducing etching quality of the subsequent sacrificial layer 30. Therefore, in some embodiments, the method of manufacturing a semiconductor structure further includes the following step:
performing a first precleaning on the first contact hole 11. In the first precleaning, the bottom and sidewall of the first contact hole 11 can be bombarded with argon ions; or the first contact hole 11 may be purged with a gas, such as nitrogen or argon. Certainly, an embodiment of the method in which the first contact hole 11 is purged with the gas is not limited thereto, and the gas for the first precleaning may alternatively be another inert gas.

In this embodiment, the particulate impurity such as the oxide in the first contact hole is removed through the first precleaning, so as to reduce residual particulate impurities, prevent the residual particulate impurities from affecting a resistance value of the subsequent sacrificial layer, improve cleanliness of the first contact hole and the purity and etching quality of the subsequent sacrificial layer, thereby improving the performance and yield of the semiconductor structure.

According to an exemplary embodiment, this embodiment is a further description of step S200 described above.

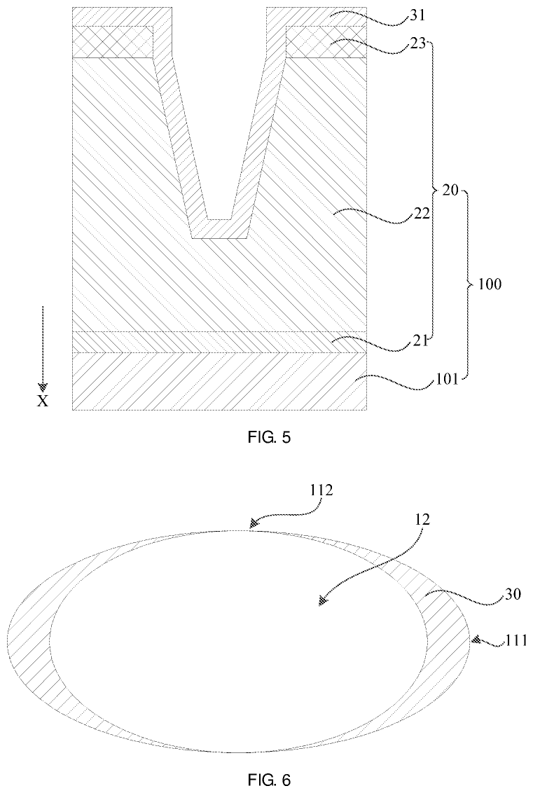

As shown in FIG. 5 and FIG. 6, the sacrificial layer 30 is formed on the long sidewall 111. In some embodiments, the sacrificial layer 30 may be formed by using the following method:
after the first precleaning is performed on the first contact hole 11, as shown in FIG. 5, forming an initial sacrificial layer 31 in the first contact hole 11 by using the atomic layer deposition process, the chemical vapor deposition process, or the physical vapor deposition process, where the initial sacrificial layer 31 covers the long sidewall 111 and the short sidewall 112.

In an example, the initial sacrificial layer 31 is formed by using the atomic layer deposition process. The atomic layer deposition process is characterized by a low deposition rate, high density of a deposited film layer, and good step coverage. The initial sacrificial layer 31 formed by using the atomic layer deposition process can be uniformly deposited on the long sidewall 111 and the short sidewall 112 of the first contact hole 11 when the initial sacrificial layer 31 is thin, to avoid occupying large space. This is conducive to subsequent filling or formation of another structure, or facilitating subsequent uniform removal of a part of the initial sacrificial layer 31 by using the etching process, so as to ensure and improve the performance and yield of the semiconductor structure.

After the initial sacrificial layer 31 is formed, the initial sacrificial layer 31 on the short sidewall 112 is removed by using the etching process, where the reserved initial sacrificial layer 31 forms the sacrificial layer 30. A material of the sacrificial layer 30 may include but is not limited to silicon nitride and silicon oxynitride.

In an example, the initial sacrificial layer 31 on the short sidewall 112 may be removed by using a wet etching process. It should be noted that the wet etching process is anisotropic and has a high etch selectivity. Therefore, when each sidewall of the first contact hole 11 is etched, the initial sacrificial layer 31 on the short sidewall 112 of the first contact hole 11 is preferentially etched, and after the initial sacrificial layer 31 on the short sidewall 112 is etched, the initial sacrificial layer 31 on the long sidewall 111 is etched. Therefore, during specific etching, provided that the initial sacrificial layer 31 on the short sidewall 112 is etched, the wet etching process can be ended, so as to remove the initial sacrificial layer 31 on the short sidewall 112 completely and retain the initial sacrificial layer 31 on the long sidewall 111. In this way, when the second contact hole 12 is formed subsequently, the initial sacrificial layer 31 on the long sidewall 111 has a certain protective effect, so as to ensure a same etching rate for the support structure layer 20 below each sidewall of the first contact hole 11. This effectively avoids the inconsistent etching lengths of the long sidewall and the short sidewall of the second contact hole, guarantees etching quality of the second contact hole 12, prevents the bridging defect, and improve the performance and yield of the semiconductor structure.

As shown in FIG. 2 to FIG. 6, in some embodiments, a forming material of the dielectric layer 21 is the same as a forming material of the sacrificial layer 30. For example, both the dielectric layer 21 and the sacrificial layer 30 are made of silicon nitride, thereby simplifying process steps and reducing a process cost.

According to an exemplary embodiment, this embodiment is a further description of step S300 described above.

As shown in FIG. 7, in some embodiments, the bottom of the first contact hole 11 is etched by using the etching process, to form the second contact hole 12 below the first contact hole 11. The second contact hole 12 is connected to the first contact hole 11, and an etching endpoint of the second contact hole 12 is located on a top surface of the base plate body 101. The plane parallel to the top surface of the semiconductor base plate 100 is taken as the cross section, and the cross-sectional area of the second contact hole 12 is less than that of the first contact hole 11.

It should be noted that, along the first direction X, except for the position at which the first contact hole 11 is connected to the second contact hole 12, cross-sectional area of the second contact hole 12 at any position is less than a minimum value of cross-sectional area of the first contact hole 11 at any position. In this embodiment, the first contact hole 11 and the second contact hole 12 form the contact through hole 10, and the contact through hole 10 is configured to subsequently form another semiconductor structure such as the contact structure. When the semiconductor structure formed in the contact through hole 10 is the contact structure, the contact structure may be a capacitor contact structure. The capacitor contact structure is configured to connect a capacitor structure and the base plate body 101 and realize an electrical connection between the capacitor structure and the base plate body 101; or the capacitor contact structure is configured to electrically connect the capacitor structure and any metal layer in the base plate body 101. Along the first direction X, the contact structure formed in the contact through hole is large at the top and small at the bottom, so as to facilitate good alignment between the subsequently formed contact structure and the capacitor structure, improve accuracy of a subsequent alignment process, and ensure the performance and yield of the semiconductor structure.

After the second contact hole 12 is formed, a second precleaning is performed on the second contact hole 12 to remove a residual particulate impurity P and the like in the process of etching the second contact hole 12, reduce residual particulate impurities, ensure cleanliness of the second contact hole 12, and improve purity of the subsequently formed contact structure or another semiconductor structure component.

As shown in FIG. 6 to FIG. 8, in some embodiments, the second precleaning performed on the second contact hole 12 includes the following step:
removing the hard mask layer 23 in the support structure layer 20 by using a dry photoresist removal process. In the dry photoresist removal process, plasma is generated in a vacuum reaction system by using a photoresist removal gas such as oxygen. Different photoresist removal rates are obtained by adjusting process parameters such as power of the vacuum reaction system and a flow of the photoresist removal gas, so as to quickly remove the hard mask layer 23. Characterized by simple operations, high photoresist removal efficiency, and low costs, the dry photoresist removal process is environmentally friendly, and makes a surface of the isolation layer 22 after photoresist removal clean, bright, and scratch-free.

After the hard mask layer 23 is removed, the remaining sacrificial layer 30 on the long sidewall 111 of the first contact hole 11 is removed by using the etching process, such as the wet etching process.

After the sacrificial layer 30 is removed, the first contact hole 11 and the second contact hole 12 form the contact through hole 10. The sidewalls and bottoms of the first contact hole 11 and the second contact hole 12 are cleaned. The bottom and sidewall of the second contact hole 12 and the sidewall of the first contact hole 11 may be bombarded with argon ions; or the first contact hole 11 and the second contact hole 12 may be purged with a gas, such as nitrogen or argon. The purge gas may alternatively be another inert gas.

In this embodiment, the hard mask layer is removed by using the dry photoresist removal process, the remaining sacrificial layer is removed by using the wet etching process, and then the contact through hole is cleaned to effectively remove a particulate impurity in the contact through hole, reduce impact of the particulate impurity, and improve the purity of the subsequently formed contact structure (such as the capacitor contact structure) or another semiconductor structure component, thereby improving the performance and yield of the semiconductor structure.

As shown in FIG. 8, an exemplary embodiment of the present disclosure provides a semiconductor structure. The semiconductor structure includes a semiconductor base plate 100.

The semiconductor base plate 100 includes a base plate body 101 and a support layer 20a disposed on the base plate body 101, and the support layer 20a is provided with a first contact hole 11. With reference to FIG. 6, a pattern of the first contact hole 11 on a preset section includes a long sidewall 111 and a short sidewall 112. In this embodiment, a plane parallel to a top surface of the base plate body 101 is taken as a cross section. Any cross section of the first contact hole 11 in a depth direction of the first contact hole 11 can be understood as the preset section, in other words, the preset section may be any cross section that is of the first contact hole 11 along a direction opposite to a first direction X and is in a predetermined height range of the support layer 20a.

A second contact hole 12 is disposed below the first contact hole 11. One end of the second contact hole 12 is connected to the first contact hole 11, and the other end of the second contact hole 12 exposes the top surface of the base plate body 101. A plane parallel to a top surface of the semiconductor base plate 100 is taken as a cross section, cross-sectional area of the second contact hole 12 is less than cross-sectional area of a partial region of the first contact hole 11, and the partial region is a region above a position at which the first contact hole 11 is connected to the second contact hole 12.

In this embodiment, the first contact hole and the second contact hole form a contact through hole. Except for the position at which the first contact hole is connected to the second contact hole, cross-sectional area of the first contact hole is greater than that of the second contact hole. The contact through hole is configured to subsequently form another semiconductor structure such as a contact structure, such that the subsequently formed contact structure is large at the top and small at the bottom, so as to facilitate good alignment between the subsequently formed contact structure and a capacitor structure, improve accuracy of a subsequent alignment process, and ensure performance and a yield of the semiconductor structure.

As shown in FIG. 8, in some embodiments, a plane parallel to a front side surface of the semiconductor base plate 100 is taken as a longitudinal section, and a shape of a longitudinal section of the first contact hole 11 includes an inverted trapezoid. That is, along an extension direction of the first direction X, an aperture of the first contact hole 11 is a tapered structure, such that a top surface of a part of the contact structure subsequently formed in the first contact hole 11 is greater than a bottom surface of the contact structure, so as to reduce alignment difficulty in a subsequent self-alignment process of the semiconductor structure, improve the performance and yield of the semiconductor structure, and improve productivity of the semiconductor structure.

Similarly, the plane parallel to the front side surface of the semiconductor base plate 100 is taken as the longitudinal section, and a shape of a longitudinal section of the second contact hole 12 includes a square, to ensure quality of the second contact hole 12, thereby improving quality of the contact structure subsequently formed in the second contact hole 12.

As shown in FIG. 8, in some embodiments, an aperture of the second contact hole 12 is the same as a minimum value of the aperture of the first contact hole 11, which can improve quality of the contact through hole 10 while reducing manufacturing difficulty of the contact through hole 10.

As shown in FIG. 8, in some embodiments, the base plate body 101 includes a semiconductor base. The semiconductor base may be made of a semiconductor material. The semiconductor material may be one or more of silicon, germanium, a silicon-germanium compound, and a silicon-carbon compound. In some embodiments, the base may be made of silicon. The use of silicon as the base is to facilitate understanding of a subsequent forming method by those skilled in the art, rather than to constitute a limitation. In an actual application process, an appropriate material of the base may be selected as required. When the base plate body 101 is the semiconductor base, a bit line structure and other semiconductor structures may be formed in the support layer 20a.

When the base plate body 101 is a metal layer, the base plate body 101 is made of at least one of tungsten, copper, aluminum, and polycrystalline silicon, and there may be one metal layer or a plurality of stacked metal layers. When the base plate body 101 is the metal layer, a metal wire layer may be formed in the support layer 20a.

It should be noted that a material of the base plate body provided in the present disclosure may include but is not limited to the above materials. Materials available for the semiconductor base plate are not listed herein, and those skilled in the art can select them based on an actual situation.

As shown in FIG. 8, in some embodiments, the support layer 20a includes a dielectric layer 21 and an isolation layer 22 that are stacked, and the dielectric layer 21 is disposed on the base plate body 101. Along the extension direction of the first direction X, a depth of the first contact hole 11 may be between one-third and two-thirds of a thickness of the support layer 20a, or may be between one-third and two-thirds of a thickness of the isolation layer 22, so as to effectively ensure conductivity of the subsequently formed contact structure while reducing difficulty of the subsequent self-alignment process of the semiconductor structure.

The embodiments or implementations of this specification are described in a progressive manner, and each embodiment focuses on differences from other embodiments. The same or similar parts between the embodiments may refer to each other.

In the description of this specification, the description with reference to terms such as “an embodiment”, “an exemplary embodiment”, “some implementations”, “a schematic implementation”, and “an example” means that the specific feature, structure, material, or characteristic described in combination with the implementation(s) or example(s) is included in at least one implementation or example of the present disclosure.

In this specification, the schematic expression of the above terms does not necessarily refer to the same implementation or example. Moreover, the described specific feature, structure, material or characteristic may be combined in an appropriate manner in any one or more implementations or examples.

It should be noted that in the description of the present disclosure, the terms such as “center”, “top”, “bottom”, “left”, “right”, “vertical”, “horizontal”, “inner” and “outer” indicate the orientation or position relationships based on the accompanying drawings. These terms are merely intended to facilitate description of the present disclosure and simplify the description, rather than to indicate or imply that the mentioned apparatus or element must have a specific orientation and must be constructed and operated in a specific orientation. Therefore, these terms should not be construed as a limitation to the present disclosure.

It can be understood that the terms such as “first” and “second” used in the present disclosure can be used to describe various structures, but these structures are not limited by these terms. Instead, these terms are merely intended to distinguish one structure from another.

The same elements in one or more accompanying drawings are denoted by similar reference numerals. For the sake of clarity, various parts in the accompanying drawings are not drawn to scale. In addition, some well-known parts may not be shown. For the sake of brevity, a structure obtained by implementing a plurality of steps may be shown in one figure. In order to understand the present disclosure more clearly, many specific details of the present disclosure, such as the structure, material, size, processing process, and technology of the device, are described below. However, as those skilled in the art can understand, the present disclosure may not be implemented according to these specific details.

Finally, it should be noted that the above embodiments are merely intended to explain the technical solutions of the present disclosure, rather than to limit the present disclosure. Although the present disclosure is described in detail with reference to the above embodiments, those skilled in the art should understand that they may still modify the technical solutions described in the above embodiments, or make equivalent substitutions of some or all of the technical features recorded therein, without deviating the essence of the corresponding technical solutions from the scope of the technical solutions of the embodiments of the present disclosure.

### INDUSTRIAL APPLICABILITY

According to the method of manufacturing a semiconductor structure and the semiconductor structure provided in the embodiments of the present disclosure, a sacrificial layer is formed on a long sidewall of a first contact hole to effectively avoid inconsistent etching lengths of a long sidewall and a short sidewall of a second contact hole in a process of forming the second contact hole, which can guarantee quality of the formed second contact hole, prevent a bridging defect, and improve performance and a yield of the semiconductor structure.

1. A method of manufacturing a semiconductor structure, comprising:
providing a semiconductor base plate with a first contact hole whose pattern on a preset section comprises a long sidewall and a short sidewall;
forming a sacrificial layer on the long sidewall; and
processing the first contact hole to form a second contact hole below the first contact hole, wherein the second contact hole is connected to the first contact hole, a plane parallel to a top surface of the semiconductor base plate is taken as a cross section, cross-sectional area of the second contact hole is less than cross-sectional area of a partial region of the first contact hole, and the partial region is a region above a position at which the first contact hole is connected to the second contact hole.

2. The method of manufacturing the semiconductor structure according to claim 1, wherein the forming a sacrificial layer on the long sidewall comprises:
forming an initial sacrificial layer in the first contact hole, wherein the initial sacrificial layer covers the long sidewall and the short sidewall; and
removing the initial sacrificial layer on the short sidewall, wherein the retained initial sacrificial layer forms the sacrificial layer.

3. The method of manufacturing the semiconductor structure according to claim 2, further comprising:
performing a first precleaning on the first contact hole.

4. The method of manufacturing the semiconductor structure according to claim 2, wherein the removing the initial sacrificial layer on the short sidewall comprises:
removing the initial sacrificial layer on the short sidewall by using a wet etching process.

5. The method of manufacturing the semiconductor structure according to claim 1, wherein the processing the first contact hole comprises:
etching a bottom of the first contact hole by using an etching process.

6. The method of manufacturing the semiconductor structure according to claim 1, wherein the providing a semiconductor base plate with a first contact hole whose pattern on a preset section comprises a long sidewall and a short sidewall comprises:
providing the semiconductor base plate comprising a base plate body and a support structure layer disposed on the base plate body; and
forming the first contact hole in the support structure layer, wherein there is a preset height between a bottom of the first contact hole and the top surface of the semiconductor base plate.

7. The method of manufacturing the semiconductor structure according to claim 6, wherein the providing the semiconductor base plate comprising a base plate body and a support structure layer disposed on the base plate body comprises:
forming a dielectric layer, an isolation layer, and a hard mask layer that are stacked on the base plate body.

8. The method of manufacturing the semiconductor structure according to claim 7, wherein a forming material of the dielectric layer is the same as a forming material of the sacrificial layer.

9. The method of manufacturing the semiconductor structure according to claim 7, further comprising:
performing a second precleaning on the second contact hole.

10. The method of manufacturing the semiconductor structure according to claim 9, wherein the performing a second precleaning on the second contact hole comprises:
removing the hard mask layer;
removing the retained sacrificial layer; and
cleaning a sidewall of the first contact hole, and a sidewall and a bottom of the second contact hole, wherein the first contact hole and the second contact hole form a contact through hole.

11. A semiconductor structure, comprising:
a semiconductor base plate, wherein the semiconductor base plate comprises a base plate body and a support layer disposed on the base plate body, the support layer is provided with a first contact hole, and a pattern of the first contact hole on a preset section comprises a long sidewall and a short sidewall; and
a second contact hole located below the first contact hole, wherein one end of the second contact hole is connected to the first contact hole and the other end of the second contact hole exposes a top surface of the base plate body, a plane parallel to the top surface of the base plate body is taken as a cross section, cross-sectional area of the second contact hole is less than cross-sectional area of a partial region of the first contact hole, and the partial region is a region above a position at which the first contact hole is connected to the second contact hole.

12. The semiconductor structure according to claim 11, wherein a shape of a longitudinal section of the first contact hole comprises an inverted trapezoid; and
a shape of a longitudinal section of the second contact hole comprises a square.

13. The semiconductor structure according to claim 12, wherein an aperture of the second contact hole is the same as a minimum value of an aperture of the first contact hole.

14. The semiconductor structure according to claim 11, wherein the base plate body comprises a semiconductor base; or
the base plate body comprises a metal layer.

15. The semiconductor structure according to claim 14, wherein the support layer comprises a dielectric layer and an isolation layer that are stacked, and the dielectric layer is disposed on the base plate body.
